(19) United States
(12) Patent Application Publication
(10) Pub. No.: US 2024/0421065 A1
(43) Pub. Date: Dec. 19, 2024

(54) METAL-INSULATOR-METAL STRUCTURE AND METHODS THEREOF

(71) Applicant: Taiwan Semiconductor Manufacturing Company, Ltd., Hsinchu (TW)

(72) Inventors: Chia-Yueh CHOU, Taoyuan City (TW); Wen-Tzu CHEN, Taoyuan City (TW); Wen-Ling CHANG, Miaoli County (TW); Hsiang-Ku SHEN, Hsinchu City (TW); Alvin Universe TANG, Hsinchu City (TW); Chun-Hsiu CHIANG, Taipei City (TW); Shin-Hung TSAI, Hsinchu City (TW); Kun-Yu LEE, Tainan City (TW); Cheng-Hao HOU, Hsinchu City (TW); Dian-Hau CHEN, Hsinchu (TW); Li-Chung YU, Kaohsiung City (TW)

(21) Appl. No.: 18/335,754

(22) Filed: Jun. 15, 2023

(51) Int. Cl. H01L 23/522; H01G 4/08; H01L 23/00

(52) U.S. Cl. CPC H01L 23/5223; H01G 4/08; H01L 24/13; H01L 2224/13147; H01L 2924/19041

(57) ABSTRACT

A method and semiconductor device including a substrate having one or more semiconductor devices. In some embodiments, the device further includes a first passivation layer disposed over the one or more semiconductor devices, and a metal-insulator-metal (MIM) capacitor structure formed over the first passivation layer. In some embodiments, the MIM capacitor structure includes a first conductor plate layer, an insulator layer on the first conductor plate layer, and a second conductor plate layer on the insulator layer. In some examples, the insulator layer includes a metal oxide sandwich structure.

### BACKGROUND

The electronics industry has experienced an ever-increasing demand for smaller and faster semiconductor devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

By way of example, and with the continued scaling of IC devices, passive devices requiring large surface areas may be fabricated as part of a back-end-of-line (BEOL) process. One example of a passive device that may be formed as part of a BEOL process is a metal-insulator-metal (MIM) capacitor. In general, a MIM capacitor includes multiple conductor plate layers that are separated from one another by dielectric layers. In some examples, MIM capacitors may be formed over a semiconductor substrate including a device layer (e.g., transistors, etc.) and a multi-layer interconnect (MLI) structure which provides interconnections between various microelectronic components within the substrate. In some embodiments, a passivation layer may be formed over the MIM capacitors, and contact vias may be formed to electrically couple lower contact features to upper contact features, such as contact pads, for connection to external circuitry. In some cases, the dielectric layer of the MIM capacitors may be degraded during subsequent processing. For instance, a high-pressure anneal (HPA) may be performed after formation of the MIM capacitors to improve the performance of front-end-of-line (FEOL) devices. However, such a process may also degrade the reliability of the dielectric layer of the MIM capacitors (e.g., such as by introducing oxygen vacancies at a dielectric layer interface).

Thus, existing techniques have not proved entirely satisfactory in all respects.

### BRIEF DESCRIPTION OF THE DRAWINGS

Aspects of the present disclosure are best understood from the following detailed description when they are read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method of forming a semiconductor device including a MIM capacitor, in accordance with some embodiments;

FIGS. 2, 3, 4, 5, 6, 7, 8, 9, 10, 11, 12, 13, 14, and 15 provide cross-sectional views of a device at intermediate stages of fabrication and processed in accordance with the method of FIG. 1, according to some embodiments;

FIG. 4A illustrates an insulator layer including a metal oxide sandwich structure, according to some embodiments; and

FIGS. 7A and 7B illustrate some alternative MIM capacitor configurations, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

Metal-insulator-metal (MIM) capacitors have been widely used in functional circuits such as mixed signal circuits, analog circuits, Radio Frequency (RF) circuits, Dynamic Random-Access Memories (DRAMs), embedded DRAMs, and logic operation circuits. In system-on-chip (SOC) applications, different capacitors for different functional circuits have to be integrated on a same chip to serve different purposes. For example, in mixed-signal circuits, capacitors are used as decoupling capacitors and high-frequency noise filters. For DRAM and embedded DRAM circuits, capacitors are used for memory storage, while for RF circuits, capacitors are used in oscillators and phase-shift networks for coupling and/or bypassing purposes. For microprocessors, capacitors are used for decoupling. As its name suggests, a MIM capacitor includes a sandwich structure of interleaving metal layers and insulator layers. An exemplary MIM capacitor includes a bottom conductor plate layer, a middle conductor plate layer over the bottom conductor plate layer, and a top conductor plate layer over the middle conductor plate, each of which is insulated from an adjacent conductor plate layer by a dielectric layer.

In various embodiments, MIM capacitors may be fabricated as part of a back-end-of-line (BEOL) process. In some examples, MIM capacitors may be formed over a semiconductor substrate including a device layer (e.g., transistors, etc.) and a multi-layer interconnect (MLI) structure which provides interconnections between various microelectronic components within the substrate. In some embodiments, a passivation layer may be formed over the MIM capacitors, and contact vias may be formed to electrically couple lower contact features to upper contact features, such as contact pads, for connection to external circuitry. In some cases, the dielectric layer of the MIM capacitors may be degraded during subsequent processing. For instance, a high-pressure anneal (HPA) may be performed after formation of the MIM capacitors to improve the performance of front-end-of-line (FEOL) devices. However, such a process may also degrade the reliability of the dielectric layer of the MIM capacitors (e.g., such as by introducing oxygen vacancies at a dielectric layer interface). Thus, existing methods have not been entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures for enhancing the reliability of the dielectric layer of MIM capacitors, and thus enhancing the reliability of the MIM capacitors themselves. Generally, embodiments of the present disclosure provide a high-k dielectric film stack, for use as a MIM capacitor insulator layer, that can meet performance and reliability targets while also being resistant to degradation from subsequent processing (e.g., such as from a subsequent high-pressure annealing process). In some embodiments, the high-k dielectric film stack includes a metal oxide sandwich structure having a same top layer (metal oxide layer X) and a bottom layer (metal oxide layer X) interposed by a stack of interleaving metal oxide layers (metal oxide layer X/metal oxide layer Y). In an example, the metal oxide layer X may include a zirconium oxide (ZrO₂) layer, and the metal oxide layer Y may include a hafnium oxide (HfO₂) layer. Thus, in some cases, the metal oxide sandwich structure may include ZrO₂ top and bottom layers interposed by a hafnium-zirconium oxide (H₂O) layer that includes interleaving HfO₂ and ZrO₂ layers. In at least some cases, a metal oxide layer of the of the stack of interleaving metal oxide layers (metal oxide layer X/metal oxide layer Y) that is in contact with the bottom layer (metal oxide layer X) of the metal oxide sandwich structure is the same as the bottom layer (metal oxide layer X). In various embodiments, a thickness of the stack of interleaving metal oxide layers (metal oxide layer X/metal oxide layer Y) is at least ten times greater than a thickness of either the top layer (metal oxide layer X) or the bottom layer (metal oxide layer X). By providing the disclosed metal oxide sandwich structure, reliability of the MIM insulator layer (and of the MIM capacitors) will be enhanced. Additional details of embodiments of the present disclosure are provided below, and additional benefits and/or other advantages will become apparent to those skilled in the art having benefit of the present disclosure.

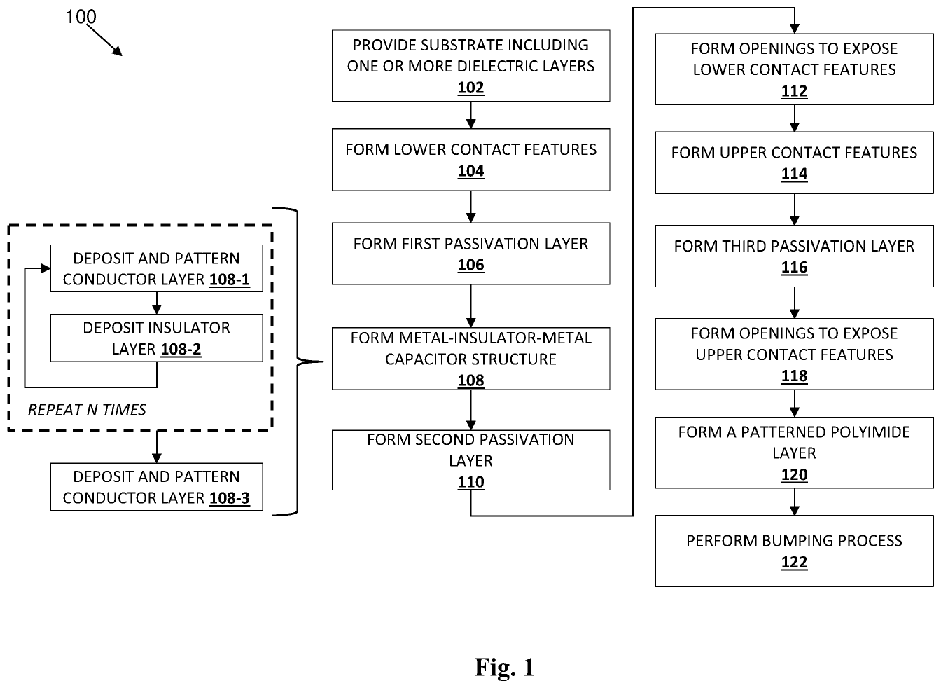

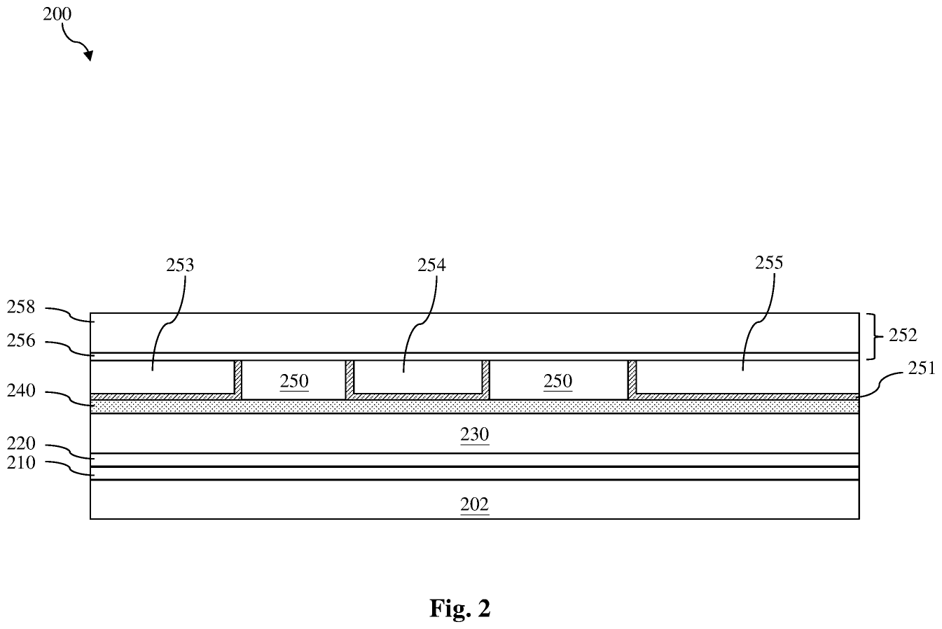

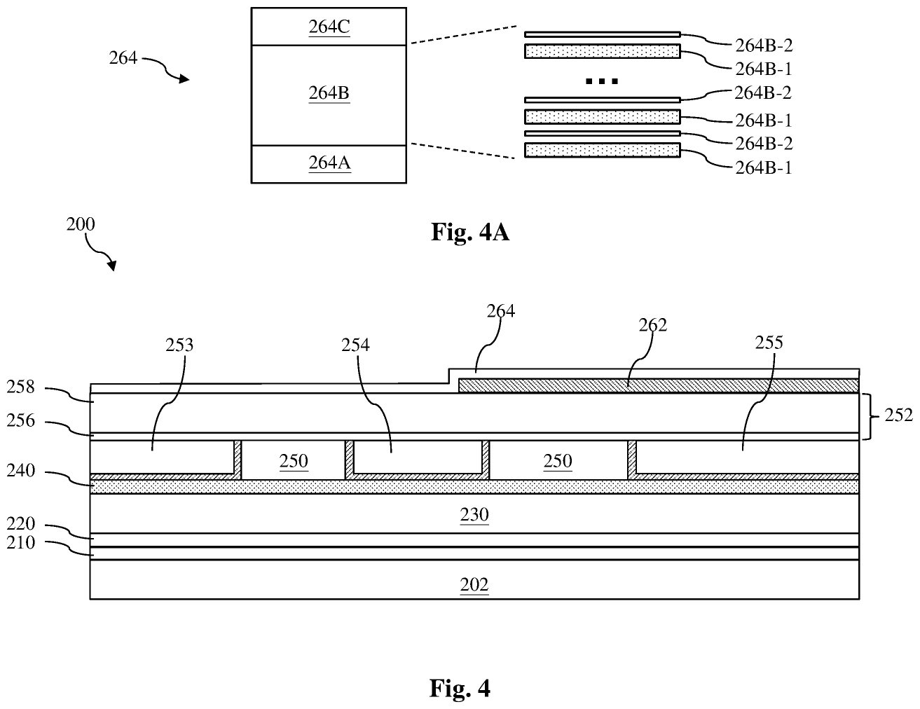

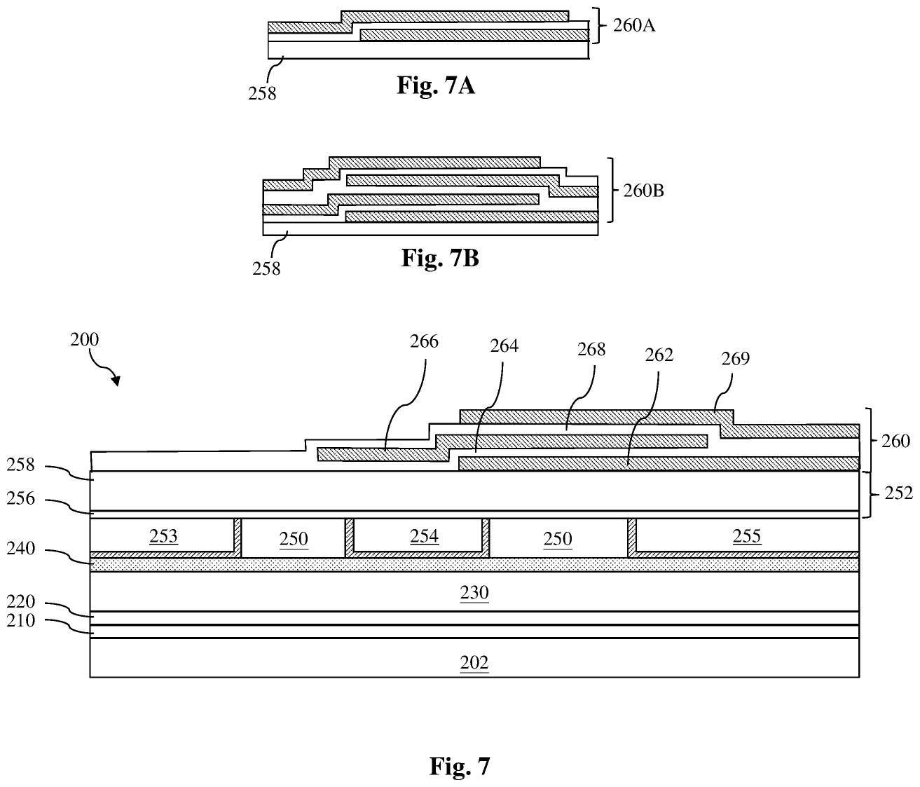

Referring now to FIG. 1, illustrated is a method 100 of forming semiconductor device including a MIM capacitor, in accordance with some embodiments. The method 100 is described below in more detail with reference to FIGS. 2-15, 4A, 7A, and 7B. FIGS. 2-15 provide cross-sectional views of a semiconductor device 200 at different stages of fabrication, FIG. 4A illustrates a high-k dielectric film stack including a metal oxide sandwich structure, and FIGS. 7A/7B illustrate some alternative MIM structure configurations (e.g., as compared to the MIM structure configuration shown in FIG. 7), according to embodiments of the present disclosure. It will be understood that the method 100 is merely an example and is not intended to limit the present disclosure to what is explicitly illustrated in the method 100. Further, additional process steps may be implemented before, during, and after the method 100, and some process steps described may be replaced or eliminated in accordance with various embodiments of the method 100. It is also noted that for clarity of discussion, not all steps are described herein in detail. In addition, parts of the method 100 may be fabricated by a well-known complementary metal-oxide-semiconductor (CMOS) technology process flow, and thus some processes are only briefly described herein.

The method 100 begins at block 102 where a substrate including one or more dielectric layers is provided. With reference to FIG. 2, and in an embodiment of block 102, a device 200 including a substrate 202 is provided. The substrate 202 may be a semiconductor substrate such as a silicon substrate. The substrate 202 may include various layers, including conductive or insulating layers formed on the substrate 202. The substrate 202 may include various doping configurations depending on design requirements as is known in the art. The substrate 202 may also include other semiconductors such as germanium, silicon carbide (SiC), silicon germanium (SiGe), or diamond. Alternatively, the substrate 202 may include a compound semiconductor and/or an alloy semiconductor. Further, in some embodiments, the substrate 202 may include an epitaxial layer (epi-layer), the substrate 202 may be strained for performance enhancement, the substrate 202 may include a silicon-on-insulator (SOI) structure, and/or the substrate 202 may have other suitable enhancement features.

In some embodiments, the substrate 202 includes one or more active and/or passive semiconductor devices such as transistors, diodes, optoelectronic devices, resistors, capacitors, sensors, or other devices. In various examples, the transistors may include source/drain features, gate structures, gate spacers, contact features, isolation structures such as shallow trench isolation (STI) structures, or other suitable components. By way of example, the active and/or passive semiconductor devices formed within the substrate 202 may be formed as part of a front-end-of-line (FEOL) process.

In various examples, the substrate 202 may also include an interconnect structure such as a multi-layer interconnect (MLI) structure, which may include multiple patterned dielectric layers and conductive layers that provide interconnections (e.g., wiring) between the various microelectronic components formed within the substrate 202. By way of example, the MLI structure, as well as other layers, features, components, or devices formed over the MLI structure may be formed as part of a BEOL process. In addition, and in at least some cases, one or more of the dielectric layers and/or conductive layers of the MLI structure may be formed over the substrate 202. As noted, the interconnect structure may include a plurality of conductive features and a plurality of dielectric features used to provide isolation between the conductive features. In some embodiments, the conductive features may include contacts, vias, or metal lines to provide horizontal and vertical interconnections. In some cases, the metal lines may include copper (Cu), aluminum (Al), an aluminum copper (AlCu) alloy, ruthenium (Ru), cobalt (Co), or other appropriate metal layer. In some examples, the contacts and/or vias may include Cu, Al, an AlCu alloy, Ru, Co, tungsten (W), or other appropriate metal layer. In some embodiments, the dielectric features of the MLI structure may include silicon oxide or a silicon oxide containing material where silicon exists in various suitable forms. In some examples, the dielectric features may include a low-k dielectric layer (e.g., having a dielectric constant less than that of SiO₂ which is about 3.9) such as tetraethylorthosilicate (TEOS) oxide, undoped silicate glass (USG), or doped silicon oxide such as borophosphosilicate glass (BPSG), fluorosilicate glass (FSG), phosphosilicate glass (PSG), boron doped silicon glass (BSG), and/or other suitable low-k dielectric material.

In some embodiments, and in a further embodiment of block 102, an interlayer dielectric (ILD) 210 is formed over the substrate 202. The ILD 210 may include silicon oxide, a silicon oxide containing material, or a low-k dielectric layer such as TEOS oxide, undoped silicate glass (USG), or doped silicon oxide such as BPSG, FSG, PSG, BSG, and/or other suitable low-k dielectric material. In various examples, the ILD 210 may be deposited by chemical vapor deposition (CVD), physical vapor deposition (PVD), atomic layer deposition (ALD), or combinations thereof. As one example, the ILD 210 may have a thickness of about 200 nm. In other embodiments, the ILD 210 may have a thickness of between about 150 nm and about 250 nm. The ILD 210 may be conformally deposited and have a substantially uniform thickness.

In some examples, and in a further embodiment of block 102, a carbide layer 220 is formed over the ILD 210. In some embodiments, the carbide layer 220 may be deposited by CVD, PVD, ALD, or combinations thereof. In some embodiments, the carbide layer 220 may include a silicon carbide (SiC) layer, although other types of carbide materials may be used. In some examples, the carbide layer 220 may have a thickness of about 55 nm. In other embodiments, the carbide layer 220 may have a thickness of between about 45 nm and about 65 nm. The carbide layer 220, in some embodiments, may be conformally deposited and have a substantially uniform thickness.

Still referring to FIG. 2, and in a further embodiment of block 102, the device 200 further includes a dielectric layer 230 formed over the carbide layer 220. In some embodiments, the dielectric layer 230 may include silicon oxide or a silicon oxide containing material. In some cases, the dielectric layer 230 may include undoped silicate glass (USG). In various examples, the dielectric layer 230 may be deposited by plasma enhanced CVD (PECVD), high-density plasma CVD (HDP-CVD), sub-atmospheric CVD (SACVD), ALD, PVD, or a combination thereof. In some cases, the dielectric layer 230 may have a thickness of about 620 nm. In other embodiments, the dielectric layer 230 may have a thickness of between about 575 nm and about 675 nm. In some embodiments, the dielectric layer 230 may be conformally deposited and have a substantially uniform thickness.

In some embodiments, and in a further embodiment of block 102, a dielectric layer 240 may be formed over the dielectric layer 230. In some cases, the dielectric layer 240 may include a nitrogen-containing material and/or a carbon-containing material. For example, the dielectric layer 240 may include silicon carbon nitride (SiCN), silicon oxycarbide (SiOC), silicon carbide (SiC), silicon oxycarbonitride (SiOCN), silicon nitride (SiN), or combinations thereof. In some embodiments, the dielectric layer 240 may have a thickness of about 50 nm. In other embodiments, the dielectric layer 240 may have a thickness of between about 45 nm and about 55 nm. In various examples, the dielectric layer 240 may be deposited by CVD, ALD, PVD, or combinations thereof. The dielectric layer 240 may, in some cases, function as an etch stop layer (ESL).

The method 100 proceeds to block 104 where lower contact features are formed. Still with reference to FIG. 2, and in an embodiment of block 104, a dielectric layer 250 may be deposited over the dielectric layer 240. In some embodiments, the dielectric layer 250 includes silicon oxide or a silicon oxide containing material. In some cases, the dielectric layer 250 may include undoped silicate glass (USG). In various examples, the dielectric layer 250 may be deposited by PECVD, HDP-CVD, SACVD, ALD, PVD, or a combination thereof. In some cases, the dielectric layer 250 may have a thickness of about 900 nm. In other embodiments, the dielectric layer 250 may have a thickness of between about 800 nm and about 1000 nm. In some embodiments, the dielectric layer 250 may be conformally deposited and have a substantially uniform thickness.

After deposition of the dielectric layer 250, and in a further embodiment of block 104, the dielectric layer 250 may be patterned to form trenches. In various examples, the dielectric layer 250 may be patterned using a suitable combination of photolithography processes (e.g., such as photoresist deposition, exposure, and development) to form an etch mask, and an etching process may be performed using the etch mask to form the trenches. In some cases, a hard mask layer (e.g., such as a nitride-containing layer) may be used as part of the patterning process of the dielectric layer 250.

In some embodiments, and in a further embodiment of block 104, lower contact features 253, 254, 255 are formed in the trenches provided by the patterning of the dielectric layer 250. Although the lower contact features 253, 254, 255 are disposed below upper contact features (discussed below), the lower contact features 253, 254, 255 are sometimes referred to as top metal (TM) contacts because they represent a top metal layer of the MLI structure, previously discussed. In some embodiments, each of the lower contact features 253, 254, 255 may include a barrier layer 251 and a metal fill layer to complete the lower contact features 253, 254, 255. By way of example, formation of the lower contact features 253, 254, 255 includes multiple processes. In some embodiments, the barrier layer 251 is formed in each of the trenches provided by the patterning of the dielectric layer 250, followed by the deposition of a metal fill layer over the barrier layer 251. In some embodiments, the barrier layer 251 includes titanium nitride, tantalum, tantalum nitride, or combinations thereof. In some embodiments, the metal fill layer includes a metal or metal alloy such as copper, cobalt, nickel, aluminum, tungsten, titanium, or combinations thereof. In some embodiments, the metal fill layer is formed by deposition or plating, followed by a chemical mechanical planarization (CMP) process.

After forming the lower contact features 253, 254, 255, the method 100 proceeds to block 106 where a first passivation layer is formed. As shown in FIG. 2, and in an embodiment of block 106, a first passivation layer 252 is formed over device 200 including over the lower contact features 253, 254, 255. In some embodiments, the first passivation layer 252 includes a dielectric layer 256 formed over the lower contact features 253, 254, 255. In some embodiments, the dielectric layer 256 is about 75 nm thick. In other embodiments, the dielectric layer 256 may have a thickness of between about 65 nm and about 85 nm. The dielectric layer 256 may include a nitrogen-containing material and/or a carbon-containing material. For example, the dielectric layer 256 may include SiCN, SiOC, SiC, SiOCN, SiN, or combinations thereof. In various examples, the dielectric layer 256 may be deposited by CVD. ALD, PVD, or combinations thereof. In some embodiments, the dielectric layer 256 may protect the lower contact features 253, 254, 255 from being oxidized.

The first passivation layer 252 may further include a dielectric layer 258 formed over the dielectric layer 256. In some embodiments, the dielectric layer 258 may include silicon oxide or a silicon oxide containing material. In some cases, the dielectric layer 258 may include undoped silicate glass (USG). The dielectric layer 258 may be deposited by PECVD, HDP-CVD, SACVD, ALD, PVD, or a combination thereof. Thus, in some cases, the dielectric layer 258 may be referred to as a plasma-enhanced oxide (PEOX). In some cases, the dielectric layer 258 may have a thickness of about 300 nm. In other embodiments, the dielectric layer 258 may have a thickness of between about 250 nm and about 350 nm.

The method 100 then proceeds to block 108 (which includes sub-blocks 108-1, 108-2, and 108-3), where a metal-insulator-metal (MIM) capacitor structure is formed. As discussed below, fabrication of a MIM capacitor structure involves multiple processes such as deposition and patterning of a plurality of conductor plates, as well as formation of insulators between adjacent conductor plates of the MIM capacitor. As indicated in the example of FIG. 1, sub-blocks 108-1 and 108-2 may be repeated N times, after which the method proceeds to sub-block 108-3 to complete the formation of the MIM capacitor. In some cases, N is equal to 0, meaning each of the sub-blocks 108-1 and 108-2 is only performed once before proceeding to sub-block 108-3, and meaning that the MIM capacitor will have two conductor plates. In another example, N is equal to 1, meaning each of the sub-blocks 108-1 and 108-2 is performed twice before proceeding to sub-block 108-3, and meaning that the MIM capacitor will have 3 conductor plates. In still another example, N is equal to 2, meaning each of the sub-blocks 108-1 and 108-2 is performed three times before proceeding to sub-block 108-3, and meaning that the MIM capacitor will have 4 conductor plates. Thus, more generally, the number of conductor plates of the MIM capacitor will be equal to N+2. In various embodiments, N is in a range of between 0-8. As such, the number of conductor plates of the MIM capacitor may be in a range of between 2-10. For purposes of the discussion that follows, it will be assumed that N is equal to 1 and the MIM capacitor has 3 conductor plates including a bottom conductor plate, a middle conductor plate, and a top conductor plate. It will be understood that this example is merely exemplary, and other values of N and other numbers of conductor plates of the MIM capacitor may equally be used, as described above, without departing from the scope of the present disclosure.

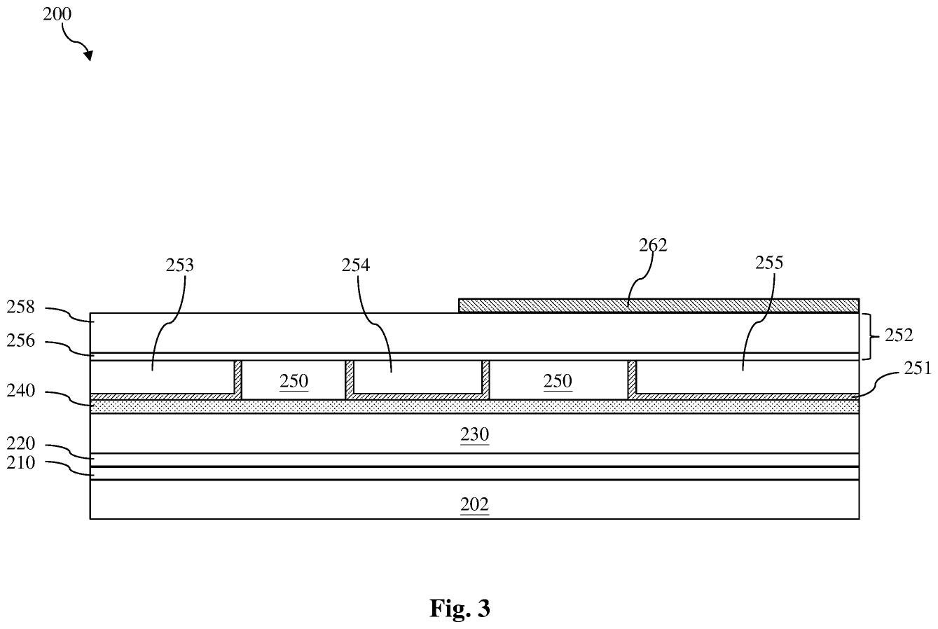

With reference now to FIG. 3, and in an embodiment of sub-block 108-1, a patterned bottom conductor plate layer 262 is formed over the dielectric layer 258. By way of example, formation of the patterned bottom conductor plate layer 262 may involve multiple processes such as layer deposition, photolithography, development, and/or etching, etc. In an embodiment, the bottom conductor plate layer 262 may include a metal nitride layer such as titanium nitride (TiN), however other metals may likewise be used. The bottom conductor plate layer 262 may go through surface treatment such as sidewall passivation using a nitrous oxide (N₂O) gas. In some embodiments, the bottom conductor plate layer 262 is about 40 nm thick. In other embodiments, the bottom conductor plate layer 262 may have a thickness of between about 35 nm and about 45 nm.

As shown in FIG. 4, and in an embodiment of sub-block 108-2, an insulator layer 264 is formed over the device 200 including over the bottom conductor plate layer 262. In an embodiment, the insulator layer 264 is conformally deposited (e.g., such as via ALD or CVD) and has a generally uniform thickness over the top surface of the device 200 (e.g., having about the same thickness on top and sidewall surfaces of the bottom conductor plate layer 262). More particularly, in accordance with embodiments of the present disclosure, the insulator layer 264 may be a high-k dielectric film stack including a metal oxide sandwich structure (tri-layer structure or multi-layer structure), as illustrated in the example of FIG. 4A. The high-k dielectric film stack includes high-k dielectric material(s) having a dielectric constant (k-value) greater than that of silicon oxide, for example, to provide increased capacitance values of the MIM capacitor. The metal oxide sandwich structure of the insulator layer 264 may include a bottom insulator layer 264A, a middle insulator layer 264B over the bottom insulator layer 264A, and a top insulator layer 264C over the middle insulator layer 264B. In various embodiments, the bottom insulator layer 264A and the top insulator layer 264C are composed of a same material. By providing this symmetry between the bottom and top insulator layers 264A, 264C, stress on the MIM capacitor from an applied voltage bias can be balanced or minimized to provide for improved reliability. The middle insulator layer 264B, which interposes the bottom and top insulator layers 264A, 264C, is composed of a stack of two types of interleaving insulator layers 264B-1 and 264B-2, each having a different material composition, where one type of insulator layer of the stack of two types of interleaving insulator layers (the insulator layers 264B-1, 264B-2) is composed of the same material (has a same material composition) as the bottom and top insulator layers 264A, 264C. In an example, the bottom insulator layer 264A and the top insulator layer 264C may include a zirconium oxide (ZrO₂) layer, and the middle insulator layer 264B may include a hafnium-zirconium oxide (H₂O) layer that includes interleaving HfO₂ and ZrO₂ layers. In some embodiments, the insulator layer 264B-1 includes a ZrO₂ layer, like the bottom and top insulator layers 264A. 264C, and the insulator layer 264B-2 includes a hafnium oxide (HfO₂) layer, thereby providing the H₂O layer. Thus, in some cases, the metal oxide sandwich structure of the insulator layer 264 may include ZrO₂ top and bottom layers interposed by an H₂O layer. In some embodiments, a bottommost layer of the stack of interleaving insulator layers 264B-1, 264B-2, that is in contact with the bottom insulator layer 264A, is composed of the same material (e.g., such as ZrO₂) as the bottom insulator layer 264A to provide for higher quality insulator material (e.g., crystallinity, reduced oxygen vacancies, etc.). While some examples of materials used for the bottom, middle, and top insulator layers 264A, 264B, 264C have been given, in some cases other materials may be used without departing from the scope of this disclosure. For instance, in some embodiments, the bottom and top insulator layers 264A, 264C may alternatively include an HfO₂ layer. In other embodiments, the middle insulator layer 264B may alternatively include an aluminum oxide (Al₂O₃) layer. In still other embodiments, the insulator layer 264 may include a bi-layer structure having an H₂O layer and a ZrO₂ layer (or an HfO₂ layer) above (as a top capping layer) or beneath (as a bottom capping layer) the H₂O layer.

In some embodiments, each of the bottom and top insulator layers 264A, 264C have a thickness of about 0.4 nm. In other embodiments, each of the bottom and top insulator layers 264A, 264C have a thickness in a range of about 0.3-0.5 nm. In some examples, the middle insulator layer 264B has a thickness in a range of about 5.6-6.5 nm. In other examples, the middle insulator layer 264B has a thickness in a range of about 5-7 nm. In various embodiments, a thickness of the stack of interleaving insulator layers 264B-1, 264B-2 (the middle insulator layer 264B) is at least ten times greater than a thickness of either the bottom insulator layer 264A or the top insulator layer 264C. In some cases, a thickness of the stack of interleaving insulator layers 264B-1, 264B-2 (the middle insulator layer 264B) may be between about 10-18 times greater than the thickness of either the bottom insulator layer 264A or the top insulator layer 264C. The number and thicknesses of each layer of the stack of interleaving insulator layers 264B-1 and 264B-2 can be selected to achieve a target total thickness, permittivity, crystal structure, interface properties between adjacent insulator layers 264B-1, 264B-2, or other properties for the middle insulator layer 264B. In some examples, a thickness of the insulator layer 264B-1 may be greater than a thickness of the insulator layer 264B-2. In other examples, a thickness of the insulator layer 264B-2 may be greater than a thickness of the insulator layer 264B-1. In still other examples, a thickness of the insulator layer 264B-1 may be substantially the same as a thickness of the insulator layer 264B-2. Generally, thicknesses of each of the bottom, middle, and top insulator layers 264A, 264B, 264C may be relatively thin to further provide increased capacitance values, while maintaining sufficient thicknesses to avoid potential dielectric breakdown in the MIM capacitor (e.g., when two capacitor plates have high potential difference, current may leak between the plates, causing breakdown).

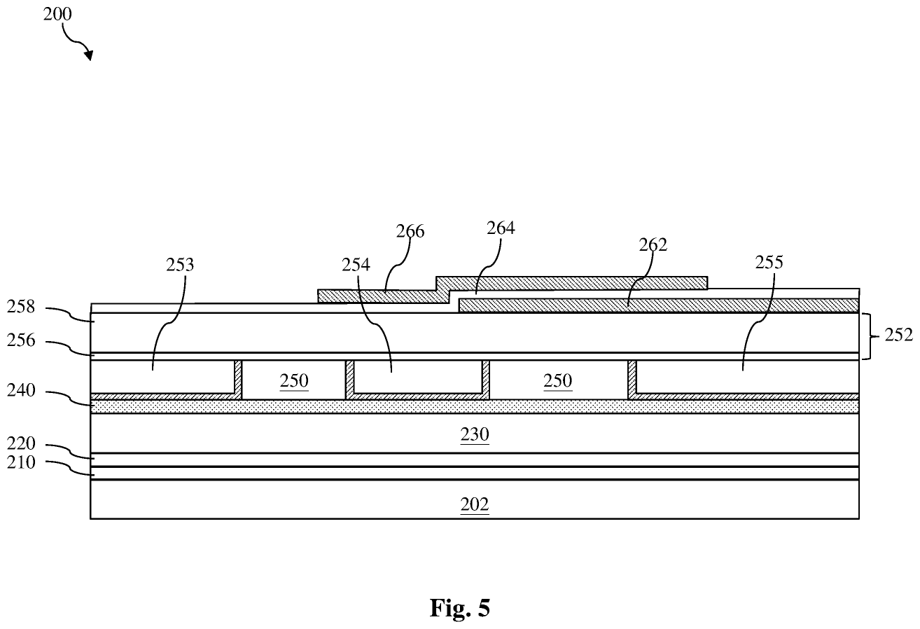

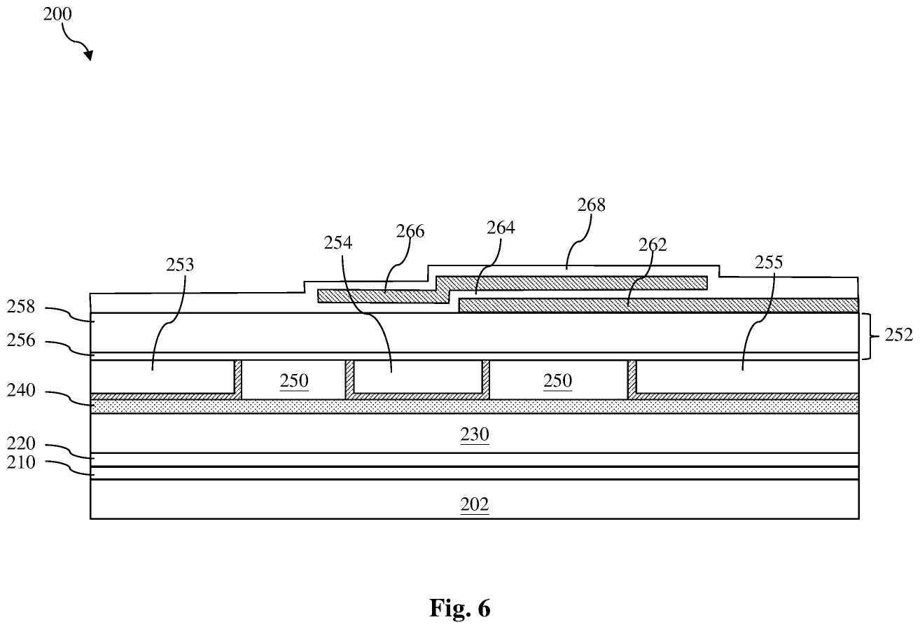

Recall that for purposes of this example, it is assumed that N is equal to 1 and the MIM capacitor will have 3 conductor plates. Thus, with reference to FIG. 1, the method 100 returns to sub-block 108-1 so that each of the sub-blocks 108-1 and 108-2 will be performed twice before proceeding to sub-block 108-3. In particular, with reference to FIG. 5 and in an embodiment of sub-block 108-1, a patterned middle conductor plate layer 266 is formed over the device 200 including over the insulator layer 264. The middle conductor plate layer 266 may be formed using a similar process to that used to form the bottom conductor plate layer 262, but the pattern of the middle conductor plate layer 266 may be different from that of the bottom conductor plate layer 262. In an embodiment, the middle conductor plate layer 266 may include a metal nitride layer such as TiN, however other metals may be used. In some embodiments, the middle conductor plate layer 266 is about 40 nm thick. In other embodiments, the middle conductor plate layer 266 may have a thickness of between about 35 nm and about 45 nm. As shown in FIG. 6, and in an embodiment of sub-block 108-2, an insulator layer 268 is formed over the device 200 including over the middle conductor plate layer 266. In an embodiment, the insulator layer 268 is conformally deposited (e.g., such as via ALD or CVD) and has a generally uniform thickness over the top surface of the device 200 (e.g., having about the same thickness on top and sidewall surfaces of the middle conductor plate layer 266). In some embodiments, the insulator layer 268 may be formed using a similar process to that used to form the insulator layer 264. Thus, in various examples, the insulator layer 268 may likewise include a metal oxide sandwich structure, such as shown in FIG. 4A, including bottom, middle, and top insulator layers. Moreover, each of the bottom, middle, and top insulator layers of the insulator layer 268 may be formed using the materials and thicknesses such as those described above with reference to the insulator layer 264.

After forming the insulator layer 268, and in accordance with the present example where N is equal to 1, the method 100 now proceeds to sub-block 108-3. As shown in FIG. 7, and in an embodiment of sub-block 108-3, a patterned top conductor plate layer 269 is formed over the device 200 including over the insulator layer 268. The top conductor plate layer 269 may be formed using a similar process to that used to form the middle conductor plate layer 266 or the bottom conductor plate layer 262, but the pattern of the top conductor plate layer 269 may be different from that of the middle conductor plate layer 266 or the bottom conductor plate layer 262. In an embodiment, the top conductor plate layer 269 may include a metal nitride layer such as titanium nitride (TiN), however other metals may be used. In some embodiments, the top conductor plate layer 269 is about 40 nm thick. In other embodiments, the top conductor plate layer 269 may have a thickness of between about 35 nm and about 45 nm.

Thus, as shown in FIG. 7, and in an embodiment of block 108, a MIM structure 260 has been formed and includes multiple metal layers including the bottom conductor plate layer 262, the middle conductor plate layer 266, and the top conductor plate layer 269, which function as metal plates of capacitors. The MIM structure 260 also includes multiple insulator layers including the insulator layer 264 disposed between the bottom conductor plate layer 262 and the middle conductor plate layer 266, as well as the insulator layer 268 disposed between the middle conductor plate layer 266 and the top conductor plate layer 269. While the MIM structure 260 in the example of FIG. 7 includes 3 conductor plates (N=1 at block 108), other configurations are possible. For instance, FIG. 7A illustrates a MIM structure 260A that includes 2 conductor plates (N=0 at block 108), and FIG. 7B illustrates a MIM structure 260B that includes 4 conductor plates (N=2 at block 108). Generally, as noted above, the number of conductor plates of the MIM capacitor is equal to N+2, and N is in a range of between 0-8. Thus, in various embodiments, the number of conductor plates of the MIM capacitor may be in a range of between 2-10. Regardless of the exact number of conductor plates in a given MIM capacitor, each conductor plate is separated from adjacent conductor plates by an insulator layer that includes a metal oxide sandwich structure, as described above. Thus, in accordance with embodiments of the present disclosure, the MIM structure formed at block 108 will be resistant to degradation from any high-pressure anneal (HPA) processes performed after formation of the MIM structure, thereby providing enhanced MIM structure reliability while improving performance of FEOL devices. Further, by way of example, the MIM structures disclosed herein (e.g., such as the MIM structures 260, 260A, 260B, or MIM structures having other configurations in accordance with the present disclosure) may be used to implement one or more capacitors, which may be connected to other microelectronic components (e.g., including active and/or passive devices, described above). In addition, and in some embodiments, the multi-layer MIM structures shown and described herein provide for close packing of capacitors in both vertical and lateral directions, thereby reducing an amount of lateral space needed for implementing capacitors. As a result, the MIM structures disclosed herein may accommodate super high-density capacitors.

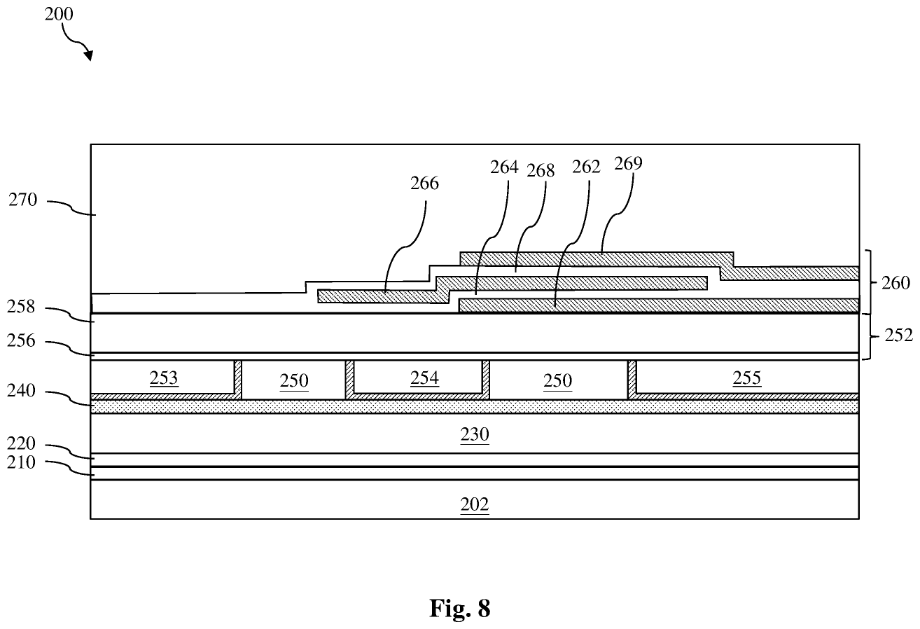

After formation of the MIM structure 260, or after formation of a MIM structure having a different number of conductor plates and insulator layers (e.g., such as the MIM structures 260A, 260B), the method 100 proceeds to block 110 where a second passivation layer is formed. As shown in FIG. 8, and in an embodiment of block 110, a second passivation layer 270 is formed over the device 200 including over the MIM structure 260. In some embodiments, the second passivation layer 270 may include a dielectric layer such as silicon oxide or a silicon oxide containing material. In some cases, the second passivation layer 270 may include undoped silicate glass (USG). The second passivation layer 270 may be deposited by PECVD, HDP-CVD, SACVD, ALD, PVD, or a combination thereof. Thus, in some cases, the second passivation layer 270 may be referred to as a plasma-enhanced oxide (PEOX). In some cases, the second passivation layer 270 may have a thickness of between about 400 nm-550 nm. As shown in FIG. 8, the MIM structure 260 is disposed between the dielectric layer 258 and the second passivation layer 270, which may include substantially the same material, in some embodiments. In some cases, and if the MIM structure 260 is not present, the dielectric layer 258 and the second passivation layer 270 may be combined as a single dielectric layer over the dielectric layer 256. Additionally, in some embodiments, a stress-reduction feature including a nitrogen-oxygen-nitrogen (NON) multi-layer structure, a nitrogen-oxygen (NO) multi-layer structure, or an oxygen-nitrogen (ON) multi-layer structure may be embedded within the second passivation layer 270 over the MIM structure 260, for example, to prevent the formation of cracks (e.g., which may propagate from nearby passivation layers) and/or other defects within metal plates of the MIM structure 260 and within insulator layers of the MIM structure 260.

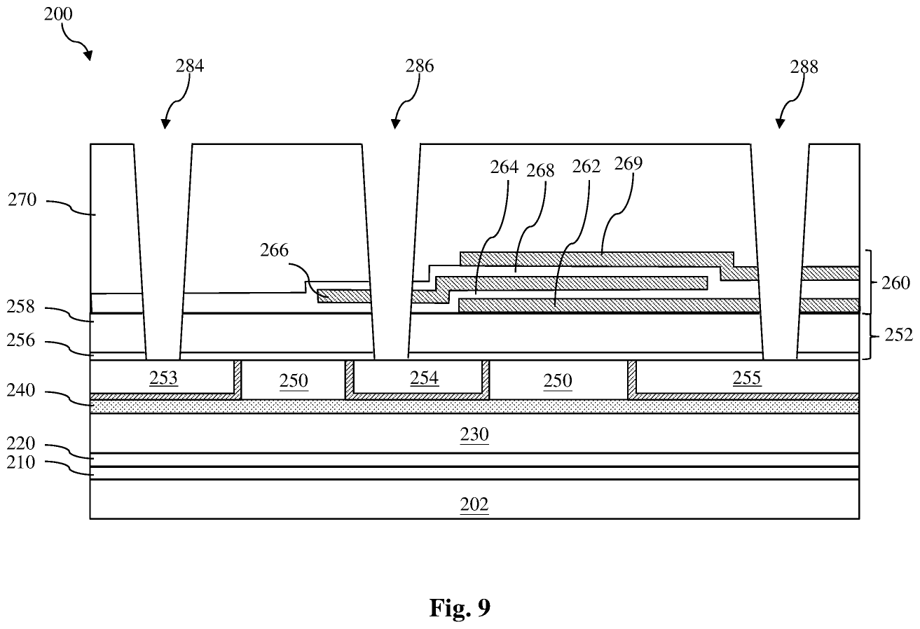

After formation of the second passivation layer 270, the method 100 proceeds to block 112 where openings are formed to expose the lower contact features. As shown in FIG. 9, and in an embodiment of block 112, openings 284, 286, 288 are formed. The opening 284 may penetrate through, from top to bottom, the second passivation layer 270, the insulator layers 268, 264 and the first passivation layer 252 (including the dielectric layer 258 and the dielectric layer 256) to expose a top surface of the lower contact feature 253. The opening 286 may penetrate through, from top to bottom, the second passivation layer 270, a portion of the MIM structure 260 (including the insulator layer 268, the middle conductor plate layer 266, and the insulator layer 264), and the first passivation layer 252 to expose a top surface of the lower contact feature 254. The opening 288 may penetrate through, from top to bottom, the second passivation layer 270, a portion of the MIM structure 260 (including the top conductor plate layer 269, the insulator layers 268, 264, and the bottom conductor plate layer 262), and the first passivation layer 252 to expose a top surface of the lower contact feature 255. In some embodiments, the openings 284, 286, 288 may be formed using an etching process (e.g., such as a dry etching process, a wet etching process, or a combination thereof). In various embodiments, sidewalls of each of the openings 284, 286, 288 may expose sidewalls of the various layers through which the openings 284, 286, 288 penetrate.

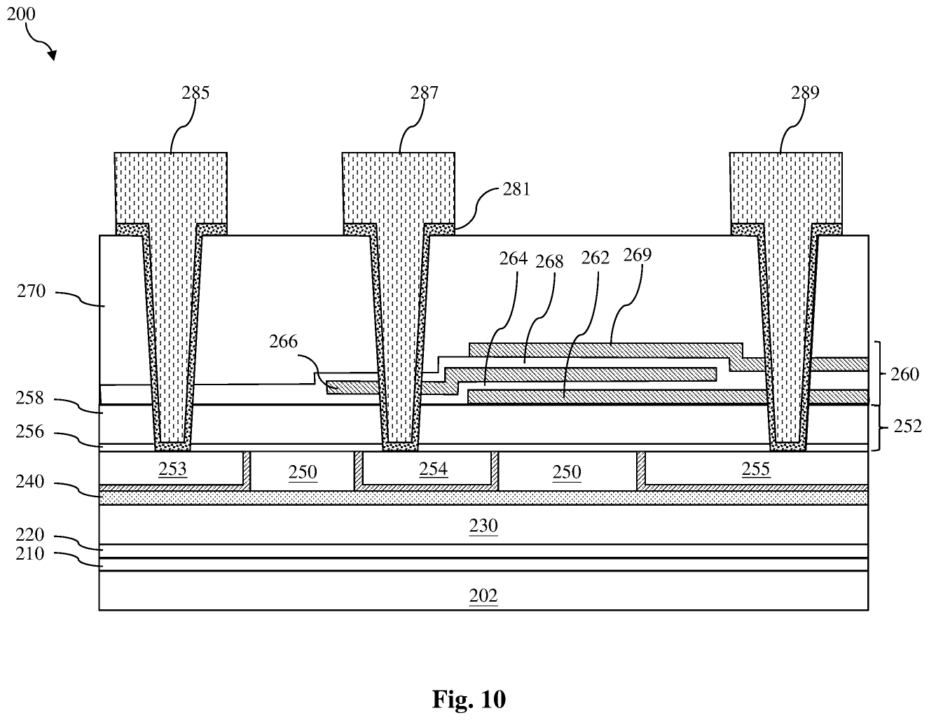

The method 100 then proceeds to block 114 where upper contact features are formed. With reference to FIG. 10, and in an embodiment of block 114, upper contact features 285, 287, 289 are formed in and over each of the openings 284, 286, 288, respectively. The upper contact features 285, 287, 289 include contact vias that fill the openings 284, 286, 288 and may be referred to as contact vias, metal vias, or metal lines. In some embodiments, to form the upper contact features 285, 287, 289, a barrier layer 281 is first conformally deposited over the second passivation layer 270 and into the openings 284, 286, 288 using a suitable deposition technique, such as ALD, PVD, or CVD, and then a metal fill layer is deposited over the barrier layer 281 using a suitable deposition technique, such as ALD, PVD, or CVD. The deposited barrier layer 281 and the metal fill layer are then patterned to form the upper contact features 285, 287, 289, as illustrated in the example in FIG. 10. In some cases, the contact features 285, 287, 289, may be referred to as contact pads. In some embodiments, the barrier layer 281 and the metal fill layer are patterned in a two-stage or multiple-stage etch process. In the example of FIG. 10, portions of the upper contact features 285, 287, 289 above the second passivation layer 270 have substantially straight sidewalls. However, in some alternative embodiments, portions of the upper contact features 285, 287, 289 above the second passivation layer 270 may have tapered sidewalls.

In some embodiments, an upper portion of the upper contact features 285, 287, 289 are part of a redistribution layer (RDL) that includes various metal lines used to redistribute bonding pads to different locations, such as from peripheral locations to being uniformly distributed on a chip surface. In various examples, the RDL couples the multi-layer interconnect (MLI) structure to the bonding pads, for connection to external circuitry. The upper contact features 285, 287, 289 provide electrical contact to the lower contact features 253, 254, 255, respectively. In addition, and as shown in the example of FIG. 10, the upper contact feature 287 is electrically coupled to the middle conductor plate layer 266, while being electrically isolated from the bottom conductor plate layer 262 and the top conductor plate layer 269. Further, the upper contact feature 289 is electrically coupled to the bottom conductor plate layer 262 and the top conductor plate layer 269, while being electrically isolated from the middle conductor plate layer 266. Thus, the upper contact feature 287 provides electrical contact to a first terminal of the MIM structure 260, and the upper contact feature 289 provides electrical contact to a second terminal of the MIM structure 260.

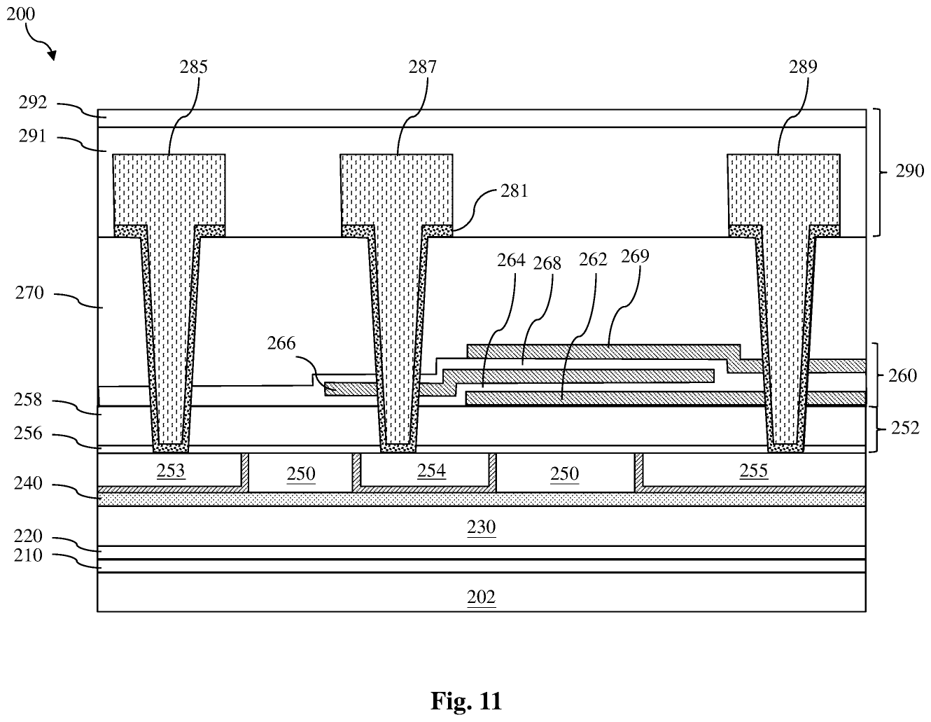

The method 100 proceeds to block 116 where a third passivation layer is formed. Referring to FIG. 11, and in an embodiment of block 116, a third passivation layer 290 is formed over device 200 including over the upper contact features 285, 287, 289 and over the second passivation layer 270. In some embodiments, the third passivation layer 290 includes a dielectric layer 291 formed over the upper contact features 285, 287, 289 and over the second passivation layer 270. In some embodiments, the dielectric layer 291 may include silicon oxide or a silicon oxide containing material. In some cases, the dielectric layer 291 may include undoped silicate glass (USG). The dielectric layer 291 may be deposited by PECVD, HDP-CVD, SACVD, ALD, PVD, or a combination thereof. Thus, in some cases, the dielectric layer 291 may be referred to as a plasma-enhanced oxide (PEOX). In some cases, the dielectric layer 291 may have a thickness of about 1200 nm. In other embodiments, the dielectric layer 291 may have a thickness of between about 1000 nm and about 1400 nm. In some examples, the third passivation layer 290 further includes a dielectric layer 292 formed over the dielectric layer 291. In some embodiments, the dielectric layer 292 is about 700 nm thick. In other embodiments, the dielectric layer 292 may have a thickness of between about 600 nm and about 800 nm. The dielectric layer 292 may include a nitrogen-containing material and/or a carbon-containing material. For example, the dielectric layer 292 may include SiCN, SiOC, SiC, SiOCN, SiN, or combinations thereof. In various examples, the dielectric layer 292 may be deposited by CVD, ALD, PVD, or combinations thereof.

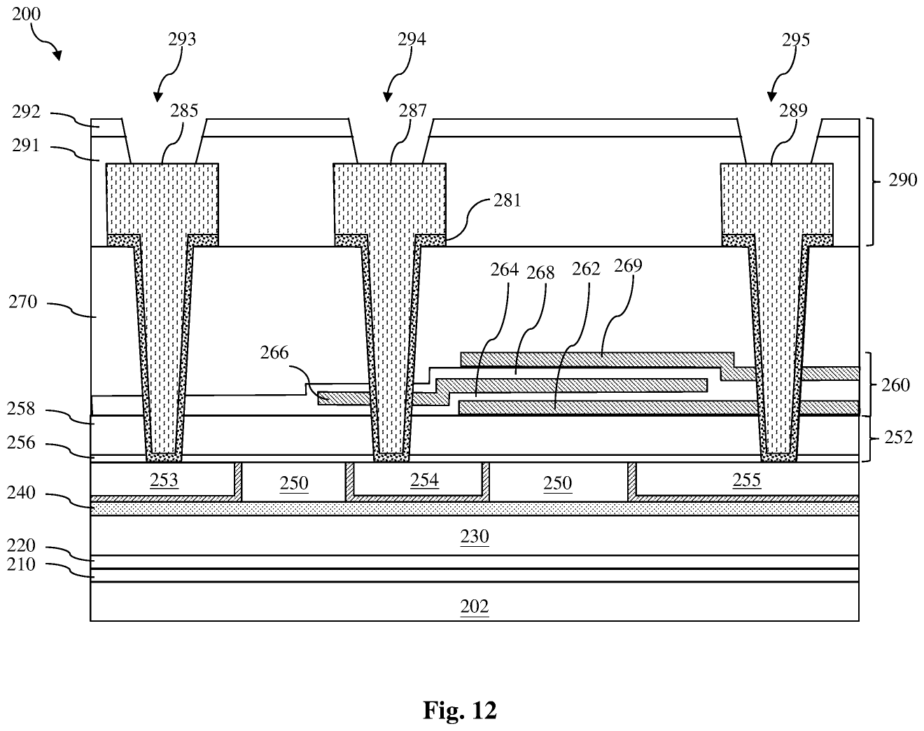

The method 100 proceeds to block 118 where openings are formed to expose the upper contact features. As shown in FIG. 12, and in an embodiment of block 118, openings 293, 294, 295 are formed. In some embodiments, each of the openings 293, 294, 295 may penetrate through, from top to bottom, the dielectric layer 292 and the dielectric layer 291 of the third passivation layer 290 to expose top surfaces of the upper contact features 285, 287, 289, respectively. In some embodiments, the openings 293, 294, 295 may be formed using an etching process (e.g., such as a dry etching process, a wet etching process, or a combination thereof). In various embodiments, sidewalls of each of the openings 293, 294, 295 may expose sidewalls of the various layers through which the openings 293, 294, 295 penetrate.

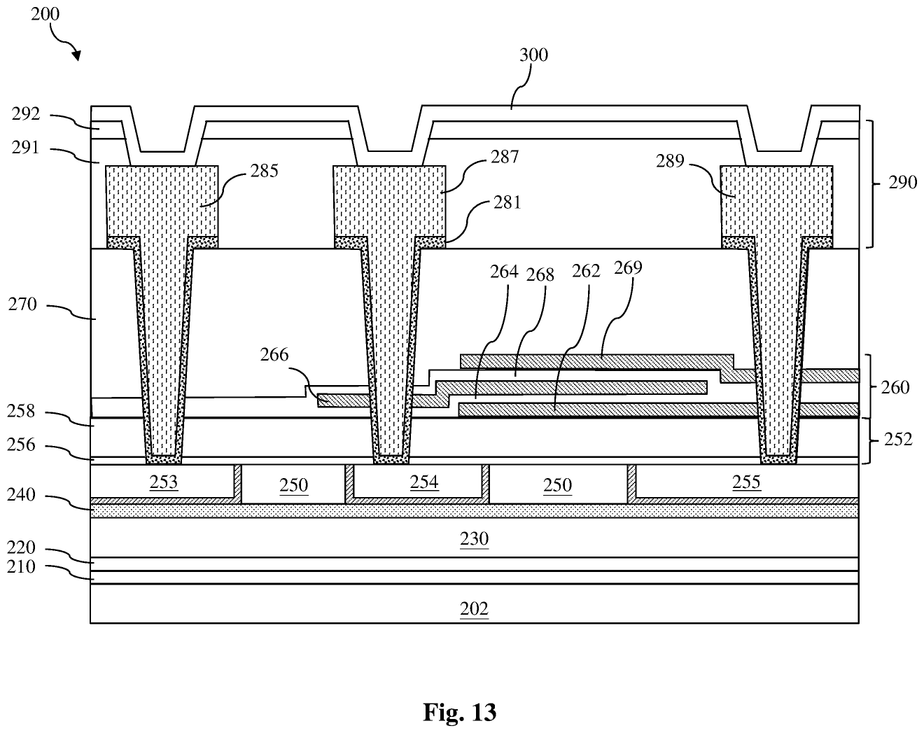

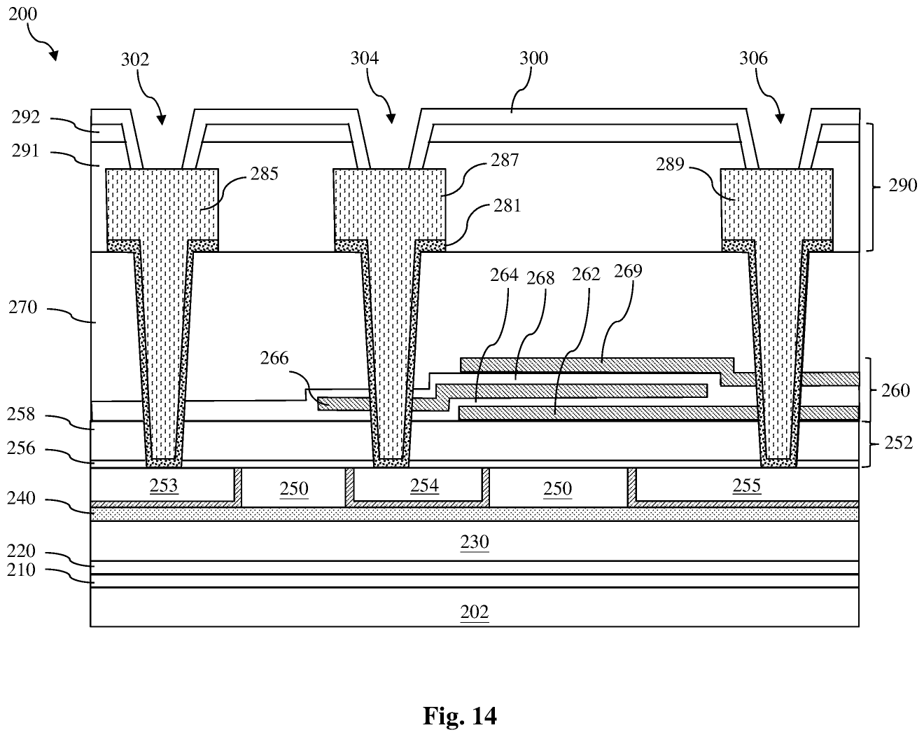

The method 100 proceeds to block 120 where a patterned polyimide (PI) layer is formed. Formation of the patterned PI layer includes multiple steps including deposition of the PI layer and patterning of the PI layer. With reference to FIGS. 13 and 14, in an embodiment of block 120, a PI layer 300 is first conformally deposited over the dielectric layer 292 and into the openings 293, 294, 295 using a suitable deposition technique, such as spin-coating. In some examples, the PI layer 300 may have a thickness of between about 5 μm and about 10 μm. In some embodiments, a baking process may be performed after deposition of the PI layer 300. The deposited PI layer 300 may then be patterned using a suitable combination of photolithography processes (e.g., such as photoresist deposition, exposure, and development) to form an etch mask, and an etching process may be performed using the etch mask to form openings 302, 304, 306 that expose top surfaces of the upper contact features 285, 287, 289, respectively. In at least some embodiments, the PI layer 300 includes a photosensitive chemical such that the PI layer 300 may be simply patterned by a photolithography process, without a subsequent etch process.

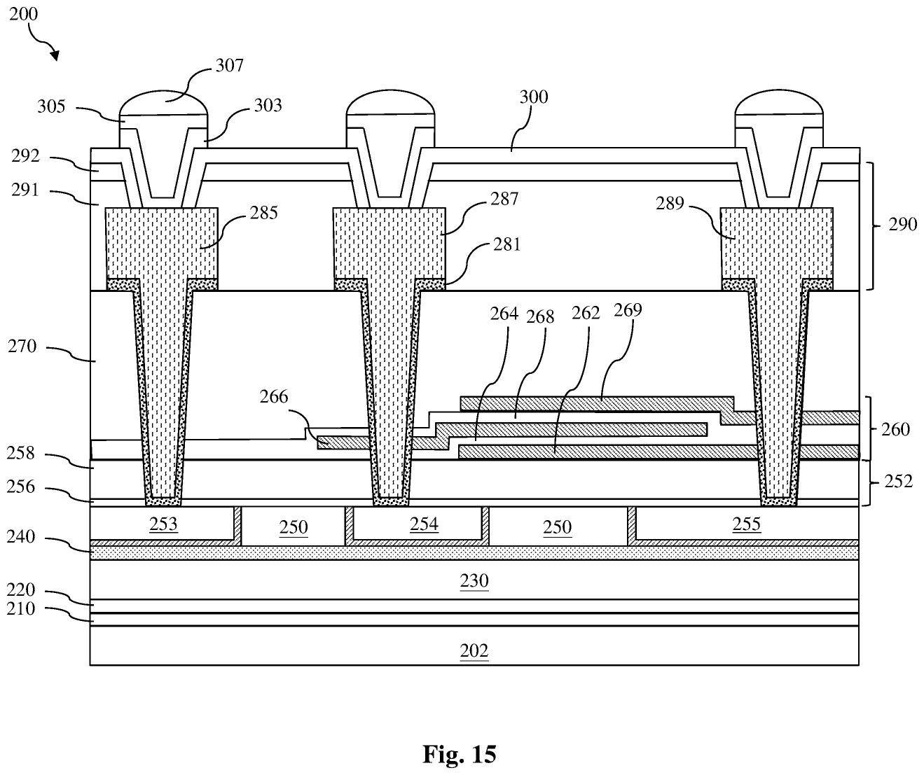

The method 100 proceeds to block 122 where a bumping process is performed. With reference to FIG. 15, in an embodiment of block 122, a bumping process includes forming of under-bump metallization (UBM) 303, a copper (Cu) pillar 305 (or Cu bump) over the UBM 303, and a solder bump 307 over the Cu pillar 305. In some embodiments, the UBM 303 provides a low resistance electrical connection to the RDL within the upper portion of the upper contact features 285, 287, 289. The UBM 303 also hermetically seals and prevents diffusion of other bump metals into the device 200. In various examples, the UBM 303 includes multiple layers of different metals such as an adhesion layer (e.g., Ti, Cr. Al or a combination thereof), a diffusion barrier layer (e.g., CrCu alloy), a solderable layer, and an oxidation barrier layer (e.g., Au). The various layers of the UBM 303 may be deposited by electroplating, sputtering, evaporation, or other suitable method. In some embodiments, a Cu seed layer may be deposited prior to formation of the Cu pillar 305, which may be formed by an electroplating process. In addition, and in some cases, a diffusion barrier (e.g., such as Ni) may be formed between the Cu pillar 305 and the solder bump 307, to prevent formation of an intermetallic layer and/or to prevent the formation of microvoids. After formation of the Cu pillar 305, a plating process may be used to form the solder bump 307 over the Cu pillar 305. One or more patterning processes (e.g., lithography and/or etching processes) may be performed to pattern one or more of the layers deposited during the bumping process. In some embodiments, a reflow process may also be performed after solder deposition to form the solder bump 307. By way of example, formation of the UBM 303, the Cu pillar 305, and the solder bump 307 provide contact structures for connection to external circuitry.

It is also that that, to improve performance of FEOL devices and in some embodiments, a high-pressure anneal (HPA) may be performed after formation of the MIM structure (block 108), including before, during, or after any of the steps 110-122 of the method 100. In an example, the HPA may be performed using hydrogen gas (H₂), at a temperature of between about 350° C. to 450° C., for a duration of between about 1-60 minutes, and at a pressure of between about 5-100 atm. However, in accordance with embodiments of the present disclosure, the metal oxide sandwich structure of the insulator layer of the MIM structure will be resistant to degradation from such HPA processes, thereby providing enhanced MIM structure reliability while improving performance of FEOL devices.

The various embodiments described herein thus offer several advantages over the existing art. It will be understood that not all advantages have been necessarily discussed herein, no particular advantage is required for all embodiments, and other embodiments may offer different advantages. As one example, embodiments discussed herein include methods and structures for enhancing the reliability of the dielectric layer of MIM capacitors, and thus enhancing the reliability of the MIM capacitors themselves. Embodiments of the present disclosure provide a high-k dielectric film stack, for use as a MIM capacitor insulator layer, where the high-k dielectric film stack includes a metal oxide sandwich structure having a same top layer (metal oxide layer X) and a bottom layer (metal oxide layer X) interposed by a stack of interleaving metal oxide layers (metal oxide layer X/metal oxide layer Y). In an example, the metal oxide layer X may include a zirconium oxide (ZrO₂) layer, and the metal oxide layer Y may include a hafnium oxide (HfO₂) layer. Thus, in some cases, the metal oxide sandwich structure may include ZrO₂ top and bottom layers interposed by a hafnium-zirconium oxide (H₂O) layer that includes interleaving HfO₂ and ZrO₂ layers. In at least some cases, a metal oxide layer of the of the stack of interleaving metal oxide layers (metal oxide layer X/metal oxide layer Y) that is in contact with the bottom layer (metal oxide layer X) of the metal oxide sandwich structure is the same as the bottom layer (metal oxide layer X). In various embodiments, a thickness of the stack of interleaving metal oxide layers (metal oxide layer X/metal oxide layer Y) is at least ten times greater than a thickness of either the top layer (metal oxide layer X) or the bottom layer (metal oxide layer X). By providing the disclosed metal oxide sandwich structure, reliability of the MIM insulator layer (and of the MIM capacitors) will be enhanced. Additional benefits and/or other advantages will become apparent to those skilled in the art having benefit of the present disclosure.

Thus, one of the embodiments of the present disclosure described a device including a substrate having one or more semiconductor devices, a first passivation layer disposed over the one or more semiconductor devices, and a metal-insulator-metal (MIM) capacitor structure formed over the first passivation layer. In some embodiments, the MIM capacitor structure includes a first conductor plate layer, an insulator layer on the first conductor plate layer, and a second conductor plate layer on the insulator layer. In some examples, the insulator layer includes a metal oxide sandwich structure.

In another of the embodiments, discussed is a device including a first passivation layer disposed over a substrate having an active semiconductor device and a metal-insulator-metal (MIM) structure formed over the first passivation layer. In some embodiments, the MIM structure includes a plurality of conductor plate layers and an insulator layer interposing adjacent conductor plate layers of the plurality of conductor plate layers. In various examples, the insulator layer includes a multi-layer structure, where the multi-layer structure includes a first zirconium oxide (ZrO₂) layer, a second ZrO₂ layer, and a hafnium-zirconium oxide (H₂O) layer interposing the first and second ZrO₂ layers.

In yet another of the embodiments, discussed is a method including depositing a first passivation layer over a substrate having one or more semiconductor devices and forming a metal-insulator-metal (MIM) capacitor over the first passivation layer. In some embodiments, forming the MIM capacitor includes forming a patterned first conductor plate over the first passivation layer, depositing an insulator layer over the patterned first conductor plate, and forming a patterned second conductor plate over the insulator layer. In some examples, the insulator layer includes a metal oxide sandwich structure having a bottom layer, a middle layer over the bottom layer, and a top layer over the middle layer. In some cases, the bottom layer and the top layer are composed of a same material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate including one or more semiconductor devices;
a first passivation layer disposed over the one or more semiconductor devices; and
a metal-insulator-metal (MIM) capacitor structure formed over the first passivation layer, wherein the MIM capacitor structure includes a first conductor plate layer, an insulator layer on the first conductor plate layer, and a second conductor plate layer on the insulator layer, and wherein the insulator layer includes a metal oxide sandwich structure.

2. The device of claim 1, further comprising a second passivation layer disposed over the MIM capacitor structure.

3. The device of claim 1, wherein the metal oxide sandwich structure includes a bottom insulator layer, a middle insulator layer over the bottom insulator layer, and a top insulator layer over the middle insulator layer, and wherein the bottom insulator layer and the top insulator layer are composed of a same material.

4. The device of claim 3, wherein the middle insulator layer is composed of a stack of two types of interleaving insulator layers having different material composition, and wherein one type of insulator layer of the stack of two types of interleaving insulator layers has a same material composition as the bottom insulator layer and the top insulator layer.

5. The device of claim 4, wherein a bottommost layer of the stack of interleaving insulator layers is composed of the same material as the bottom insulator layer and the top insulator layer.

6. The device of claim 3, wherein the bottom insulator layer and the top insulator layer include a zirconium oxide (ZrO₂) layer.

7. The device of claim 3, wherein the middle insulator layer includes a hafnium-zirconium oxide (H₂O) layer that includes interleaving HfO₂ and ZrO₂ layers.

8. The device of claim 3, wherein a first thickness of the middle insulator layer is at least ten times greater than a second thickness of either the bottom insulator layer or the top insulator layer.

9. The device of claim 2, further comprising:
a multi-layer interconnect (MLI) structure at least partially disposed within the substrate, wherein the first passivation layer is disposed over the MLI structure.

10. The device of claim 9, further comprising:
a contact feature disposed over the second passivation layer, wherein the contact feature is electrically coupled to the MLI structure.

11. The device of claim 10, wherein an upper portion of the contact feature includes a redistribution layer (RDL).

12. The device of claim 10, further comprising:
a third passivation layer disposed over the second passivation layer, wherein the contact feature is disposed within the third passivation layer.

13. A device, comprising:
a first passivation layer disposed over a substrate including an active semiconductor device; and
a metal-insulator-metal (MIM) structure formed over the first passivation layer, wherein the MIM structure comprises:
a plurality of conductor plate layers; and
an insulator layer interposing adjacent conductor plate layers of the plurality of conductor plate layers;
wherein the insulator layer includes a multi-layer structure, and wherein the multi-layer structure includes a first zirconium oxide (ZrO₂) layer, a second ZrO₂ layer, and a hafnium-zirconium oxide (H₂O) layer interposing the first and second ZrO₂ layers.

14. The device of claim 13, further comprising a second passivation layer disposed over the MIM structure.

15. The device of claim 13, wherein the H₂O layer includes a stack of interleaving insulator layers, and wherein a bottommost layer of the stack of interleaving insulator layers includes a third ZrO₂ layer.

16. The device of claim 13, wherein a first thickness of the H₂O layer is at least ten times greater than a second thickness of either the first ZrO₂ layer or the second ZrO₂ layer.

17. The device of claim 13, wherein a number of conductor plate layers in the plurality of conductor plate layers is between about 2 and 10.

18. A method, comprising:
depositing a first passivation layer over a substrate including one or more semiconductor devices; and
forming a metal-insulator-metal (MIM) capacitor over the first passivation layer, wherein the forming the MIM capacitor includes:
forming a patterned first conductor plate over the first passivation layer;
depositing an insulator layer over the patterned first conductor plate, wherein the insulator layer includes a metal oxide sandwich structure having a bottom layer, a middle layer over the bottom layer, and a top layer over the middle layer, and wherein the bottom layer and the top layer are composed of a same material; and
forming a patterned second conductor plate over the insulator layer.

19. The method of claim 18, wherein the bottom layer and the top layer each include a zirconium oxide (ZrO₂) layer, and wherein the middle layer includes a hafnium-zirconium oxide (H₂O) layer.

20. The method of claim 18, wherein the forming the MIM capacitor further includes:
prior to forming the patterned second conductor plate layer, forming one or more additional conductor plates over the insulator layer, wherein the one or more additional conductor plates also include the insulator layer interposing adjacent conductor plates of the one or more additional conductor plates, and wherein the insulator layer is also deposited over a topmost conductor plate of the one or more additional conductor plates.
